(19) United States
(12) Patent Application Publication
(10) Pub. No.: US 2009/0320915 A1
(43) Pub. Date: Dec. 31, 2009

(54) HETEROELECTRICAL PHOTOCELL

(76) Inventor: Valentin Nikolaevich SAMOILOV, Dubna Moskovskoj obl. (RU)

Correspondence Address: HOUSTON ELISEEVA, 4 MILITIA DRIVE, SUITE 4, LEXINGTON, MA, 02421, US

(21) Appl. No.: 12/497,933

(22) Filed: Jul. 6, 2009

Related U.S. Application Data
(63) Continuation of application No. PCT/RU2007/000427, filed on Aug. 3, 2007.

(30) Foreign Application Priority Data
Jan. 9, 2007 (RU) 2007100004

(51) Int. Cl. H01L 31/0248

(52) U.S. Cl. 136/255

(57) ABSTRACT

The invention relates to devices used for high-efficiently converting the energy of a electromagnetic (light) radiation into electric power and can be used for producing solar cells. Said invention makes it possible to substantially increase the performance of a photocell by inserting metal nanoparticles closed in a polymer envelop into a photosensitive layer, thereby making it possible to form a second semiconductop-polymer-metal junction, and by the possibility of converting the electromagnetic (light) radiation into electric power in a visible and infrared light spectrum.

### RELATED APPLICATIONS

This application is a Continuation of International Application No. PCT/RU2007/000427, filed on Aug. 3, 2007, which claims priority to Russian Patent Application No. 2007100004, filed on Jan. 9, 2007, both of which are incorporated herein by reference in their entirety.

### FIELD OF THE INVENTION

The invention relates to devices used for high-efficiently converting the energy of a electromagnetic (light) radiation into electric power and can be used for producing solar cells. Said invention makes it possible to substantially increase the performance of a photocell by inserting metal nanoparticles closed in a polymer envelop into a photosensitive layer, thereby making it possible to form a second semiconductop-polymer-metal junction, and by the possibility of converting the electromagnetic (light) radiation into electric power in a visible and infrared light spectrum.

### BACKGROUND OF THE INVENTION

A photocell [1] is also known that includes a metallic wafer, with a photosensitive layer applied to that wafer that contains a layer of a n-type semiconductor and a layer of poly-T-epoxypropylcarbazole doped with SbCl₅, and a semitransparent gold film. A deficiency of said photocell is the low efficiency of the converter, which reaches only 3.2% at a maximum.

A photocell [2] is also known which is chosen as the prototype of this invention. Said photocell consists of a metal wafer on which are situated p and n semiconductor layers with a pn junction between them, with metal nanoparticles inserted into the n-type semiconductor, whose size is much less than the wavelength of the radiation indicated at a concentration of said nanoparticles in said layer of (1-5)·10⁻² volume fractions, and a transparent electricity-conducting layer.

A deficiency of said photocell is also the insufficiently high efficiency of the conversion of electromagnetic light radiation energy to electrical power in the predetermined spectral range, which does not exceed 10%, and the low photovoltage, which does not exceed 0.7 V.

### SUMMARY OF THE INVENTION

The objective of this invention is the elimination of said deficiencies and the augmentation of the efficiency and the photovoltage. The stated objective is achieved by the fact that in the known photocell that converts electromagnetic radiation to electrical power and that contains p- and n-type semiconductor layers disposed on a metal wafer with a pn junction between them, with nanoparticles of metal inserted into the n-type semiconductor, whose size is much less than the wavelength of the radiation indicated at a concentration of said nanoparticles in said layer of (1-5)·10⁻² volume fractions, said nanoparticles, closed in an envelope having a form similar to the form of the surface of said nanoparticles and made of a polymer, for example, PVP (poly(2-vinylpyridine)), of a thickness of the order of the characteristic size of said nanoparticles, are inserted into said n-type semiconductor layer, and also owing to the fact that said nanoparticles, closed in the polymer envelope, are disposed in said layer in an ordered fashion, for example, in the form of a cubic lattice, and are identically oriented relative to the surface of said n-type semiconductor layer.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

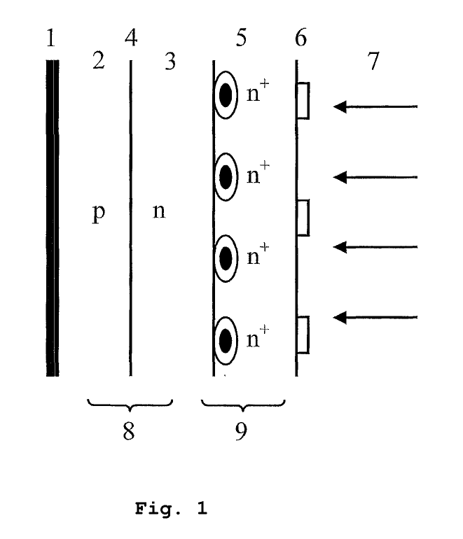

A schematic diagram of the proposed photocell is shown in FIG. 1, where:

1—metal wafer,

2—p-type semiconductor layer,

3—n-type semiconductor layer,

4—pn junction region,

5—metal nanoparticles, closed in a polymer envelope and fixed by a transparent polymer layer,

6—electrical contacts,

7—incident radiation,

8—pn junction cascade photocell,

9—n-n⁺ junction cascade photocell.

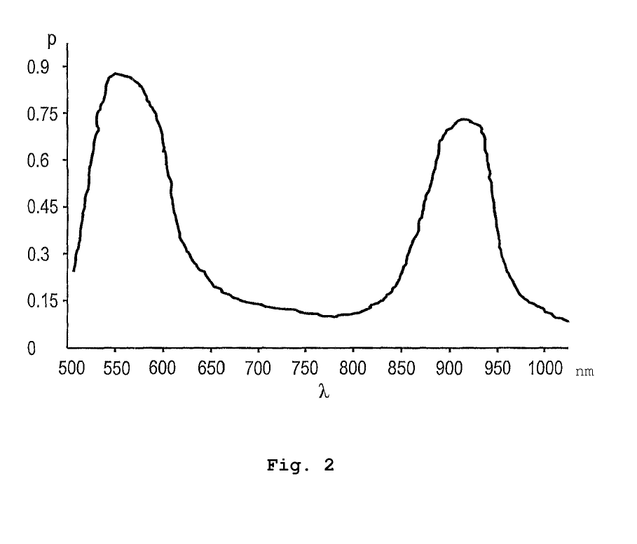

The relationship of the absorption ρ of the incident electromagnetic radiation to its wavelength λ for the proposed heteroelectrical photocell is depicted in FIG. 2.

### DETAILED DESCRIPTION OF THE PREFERRED EMBODIMENTS

The proposed heteroelectrical photocell (FIG. 1) operates in the following manner. Metal, for example gold, nanoparticles have a plasmon resonance approximately in the 550 nm region of wavelengths. With enclosure in the PVP polymer envelope, the region of wavelengths of said resonance expands and shifts to a region of longer wavelengths. Like a nanoparticle, the polymer envelope has a plasmon resonance approximately in the 900 nm region of wavelengths, i.e., in the region of infrared radiation. Thus, the gold nanoparticles, closed in the PVP envelope, when inserted into the n-type semiconductor have two clearly defined regions of absorption of electromagnetic radiation (FIG. 2).

In addition, when nanoparticles measuring 40-50 nm are used, a new resonance results for the quadrupole constituent of the radiation. For example, for the case of a spherical particle, the resonance condition is 2Reε+3=0, where ε is the dielectric function of the material of the nanoparticle.

The nanoparticles inserted into the semiconductor in an orderly and uniformly oriented manner yield additional narrow plasmon resonances.

Thus, the efficiency of the heteroelectrical photocell may reach 80% and more in sunny weather, and no less than 50% in overcast weather when a silicon semiconductor is used.

Thus, the increase in photovoltage in the heteroelectrical photocell results from the possibility of the spatial separation of charges, not only in the semiconductor pn junction, but also in the semiconductor-polymer-metal junction region where, just as in the pn junction, strong internal electrostatic fields of the double layer of charges arise [3]. The appearance of an additional (n-n⁺) junction at the boundary of the layer of a n-type layer and the PVP envelope of the nanoparticles leads to the creation of a “second cascade” in the heteroelectrical photocell, and it precisely in this near-surface region that the most efficient concentration of the light field by the nanoparticles takes place.

The metal nanoparticles closed in the polymer envelope absorb incident radiation 7 and re-emit part of it in the form of a spherical wave. In the process, the energy density W of the re-emitted incident radiation of the near zone [4, 5] proves to be several times greater than the energy density of the incident radiation. Thus, the nanoparticles “concentrate” the near-zone incident radiation like ordinary lenses or optical resonators.

The closer to the surface of semiconductor 3 the nanoparticles are, the more strongly the energy density of the re-emitted electromagnetic radiation is increased, as compared with the energy density of incident radiation 7. In connection with the fact that the internal field in the region of the pn junctions rapidly separates the photoinduced carriers such that they do not have time to recombine, the photocurrent density is proportional to W [5].

Thus, the heteroelectrical photocell combines mechanisms of augmentation of photocurrent generation in multi-cascade photocells and the “concentration” of electromagnetic fields in the region of the pn and (n-n⁺) junctions; this leads to a substantial increase in photocurrent and photovoltage and correspondingly in the efficiency of the proposed multi-cascade heteroelectrical photocell.

An example of the embodiment of the proposed dielectric photocell:

A standard p-type semiconductor wafer, covered on one side by a metal layer (for example, by the vacuum deposition method), is doped on the other side with a w-type mixture [sic] to a predetermined depth. Spherical nanoparticles of gold, 40-50 nm in diameter, obtained by the method of adsorption from hydrosol, are covered by a PVP envelope by the method of adsorption in a 0.5% solution of said polymer in chloroform. The 40-50 nm thickness of the envelope is achieved by selection of the time the nanoparticles remain in said solution. Further, said nanoparticles closed in a PVP envelope are applied by the discontinuous film method to the doped side of said p-type semiconductor wafer. after which they are fixed by application of a thin transparent polymer, in particular of the APS (γ-aminopropyltrimethoxyline) used here. Then metal strip contacts are applied, for example by the vacuum deposition method. The heteroelectrical photocell fabricated in this manner has an efficiency of about 70% in sunny weather and no less than 40% in overcast weather, and a photovoltage no less than 1.5 V.

### REFERENCES

1. N. F. Guba and V. D. Pokhodenko, AC SU 1806424 A3.

2. O. A. Zaymidoroga, I. E. Protsenko, and V. N. Samoylov, RU 2222846 CI.

3. R. Bube, Fotovodimost' tverdykh tel [Translated from English: Photoconductivity of Solids], Moscow, Inostrannaya literatura, 1962, p. 144.

4. L. D. Landau and E. M. Lifshits, Field Theory, Moscow, Nauka, 1988, p. 253.

5. S. Sze, Fizika poluprovodnikovykh priborov [Translated from English: The Physics of Semiconductor Devices], book 2, Moscow, Mir, 1984, p. 403.

While this invention has been particularly shown and described with references to preferred embodiments thereof, it will be understood by those skilled in the art that various changes in form and details may be made therein without departing from the scope of the invention encompassed by the appended claims.

1: A heteroelectrical photocell converting incident electromagnetic radiation into electric power, comprising
a metal wafer;
a p-type semiconductor layer and an n-type semiconductor layer on the metal wafer with a pn junction between the layers; and
metal nanoparticles in contact with the n-type semiconductor layer,
wherein sizes of the nanoparticles are less than the wavelength of the incident electromagnetic radiation,
wherein volume concentration of the nanoparticles is between 1·10⁻² and 5·10⁻²,
wherein the nanoparticles are enclosed in similarly shaped polymer envelopes, and
wherein thicknesses of the envelopes is between 0.1 times and 10 times the size of the nanoparticles.

2: The heteroelectrical photocell according to claim 1, wherein the nanoparticles are positioned in a pattern and are substantially identically oriented relative to the n-type semiconductor layer.

3: The heteroelectrical photocell according to claim 1, wherein the polymer is PVP (poly (2-vinylpyridine)).

4: The heteroelectrical photocell according to claim 2, wherein the pattern is a cubic lattice.
